(19) United States
(12) Patent Application Publication
(10) Pub. No.: US 2023/0118702 A1
(43) Pub. Date: Apr. 20, 2023

(54) Method, device and computer readable storage medium for estimating SOC of lithium battery

(71) Applicant: SHENZHEN POWEROAK NEWENER CO.,LTD, Shenzhen (CN)

(72) Inventors: Hui Ma, Shenzhen (CN); Wentao Cang, Shenzhen (CN); Jianhua Lei, Shenzhen (CN)

(21) Appl. No.: 17/893,416

(22) Filed: Aug. 23, 2022

Related U.S. Application Data
(63) Continuation of application No. PCT/CN2022/081476, filed on Mar. 17, 2022.

(30) Foreign Application Priority Data
Oct. 19, 2021 (CN) 20211121580.X

(51) Int. Cl. G06N 7/00; H01M 10/44

(52) U.S. Cl. CPC G06N 7/005; H01M 10/443

(57) ABSTRACT

The present disclosure discloses a method, device and computer readable storage medium for estimating SOC of a lithium battery. State data and corresponding SOC values of lithium batteries under different working conditions are collected to establish a sample set, and clustering analysis is performed on the sample set to obtain a plurality of sample subsets; obtain sub-model functions of the plurality of sample subsets; the state data of a sample to be tested is respectively added into the state data of each of the sample subsets to calculate a change value of the state data of each of the sample subsets before and after the adding operation, and at least one sub-model close to the sample to be tested is selected as the selected sub-model according to the change value; a weight is assigned to the selected sub-model to calculate the SOC value of the sample to be tested.

### CROSS-REFERENCE TO RELATED APPLICATIONS

This application is a continuation of International Application No. PCT/CN2022/081476, with an international filing date of Mar. 17, 2022, which is based upon and claims priority to Chinese Patent Application No. 202111215850.X, filed with the Chinese Patent Office on Oct. 19, 2021, titled “METHOD, DEVICE AND COMPUTER READABLE STORAGE MEDIUM FOR ESTIMATING SOC OF LITHIUM BATTERY”, the entire contents of which are incorporated herein by reference.

### TECHNICAL FIELD

The present disclosure relates to the technical field of lithium batteries, and for example, relates to a method, device and computer readable storage medium for estimating SOC of a lithium battery.

### BACKGROUND

With the development of lithium battery manufacturing and integration technology, advantages of lithium-ion batteries, such as a high energy density, a high unit voltage and a long cycle life, have been continuously excavated, and thus lithium-ion batteries have become the mainstream choice of new energy vehicles, energy storage power supplies and other systems. For energy storage power supplies, how to estimate the state of charge (SOC) of lithium batteries accurately and in real time is one of the core technologies of the energy storage power supplies. Accurate SOC estimation can avoid abnormal working modes such as over-charge and over-discharge of batteries, prolong the service life of batteries and reduce the incidence of safety accidents.

However, in the prior art, mapping relationships between battery voltage, current, temperature or the like and SOC are usually obtained by off-line training with machine learning algorithms, and then the measured data is substituted into the model to calculate the estimated SOC value. However, this method usually constructs a single global model, which is not conducive to representing the local process characteristics of SOC under multiple working conditions, and leads to insufficient accuracy and poor reliability of SOC estimation.

### SUMMARY

The present disclosure discloses a method, device and computer readable storage medium for estimating SOC of a lithium battery.

An embodiment of the present disclosure discloses a method for estimating SOC of a lithium battery, and the method includes steps of:

collecting state data and corresponding SOC values of lithium batteries under different working conditions and establishing a sample set, and performing clustering analysis on the sample set to obtain a plurality of sample subsets;

establishing a corresponding sub-model for each of the sample subsets to obtain sub-model functions of the plurality of sample subsets;

adding the state data of a sample to be tested respectively into the state data of each of the sample subsets, calculating a change value of the state data of each of the sample subsets before and after the adding operation, and selecting at least one sub-model close to the sample to be tested as the selected sub-model according to the change value;

assigning a weight to the selected sub-model, and calculating the SOC value of the sample to be tested.

An embodiment of the present disclosure discloses a computer readable storage medium having computer executable instructions stored therein, and the computer executable instructions enable a computer to execute the method described above.

An embodiment of the present disclosure discloses an electronic equipment which includes:

at least one processor; and

a memory communicatively connected with the at least one processor; wherein

the memory stores instructions executable by the at least one processor, and the instructions are executed by the at least one processor to enable the at least one processor to execute the method as described above.

An embodiment of the present disclosure discloses a computer program product comprising a computer program stored on a nonvolatile computer readable storage medium, the computer program includes program instructions which, when executed by an electronic equipment, enable the electronic equipment to execute the method as described above.

### BRIEF DESCRIPTION OF THE DRAWINGS

One or more embodiments are illustrated by corresponding attached drawings, and this does not constitute limitation of the embodiments. Element labeled with the same reference numerals in the attached drawings represent similar elements, and unless otherwise stated, figures in the attached drawings do not constitute scale limitation.

FIG. 1 is a flowchart diagram of a method for estimating SOC of a lithium battery according to some embodiments of the present disclosure.

FIG. 2 is a diagram illustrating an estimation result of a method for estimating SOC of a lithium battery according to some embodiments of the present disclosure.

FIG. 3 is a structural block diagram of a device for estimating SOC of a lithium battery according to some embodiments of the present disclosure.

FIG. 4 is a schematic view illustrating the hardware structure of an electronic equipment adapted to a method for estimating SOC of a lithium battery according to some embodiments of the present disclosure.

### DETAILED DESCRIPTION

In order to make objectives, technical solutions and advantages of the present disclosure clearer, the present disclosure will be further described in detail hereinafter with reference to attached drawings and embodiments. It shall be appreciated that, the specific embodiments described herein are used to explain the present disclosure, and are not used to limit the present disclosure.

It shall be noted that, all features in the embodiments of the present disclosure may be combined with each other without conflict, and all the combinations are within the scope claimed in the present disclosure. In addition, although functional module division is made in the schematic diagrams of the device and logical sequences are shown in the flowchart diagrams, in some cases, the steps shown or described can be executed with module division or sequences different from those in the schematic diagrams of the device and the flowchart diagrams.

Unless otherwise defined, all technical and scientific terms used in this specification have the same meanings as commonly understood by those skilled in the art of the present disclosure. The terms used in the specification of the present disclosure are for the purpose of describing specific embodiments, and are not intended to limit the present disclosure. The term “and/or” used in this specification includes any and all combinations of one or more associated items listed.

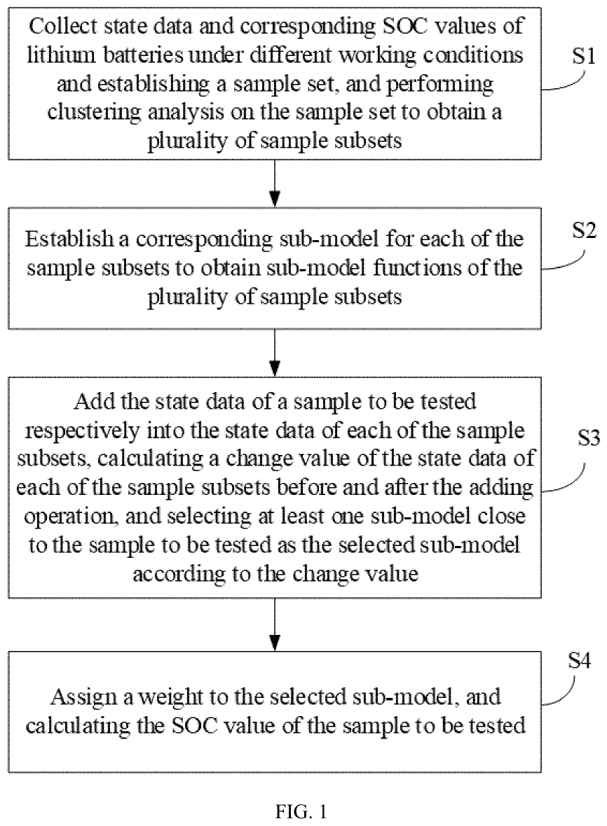

Please refer to FIG. 1, which is a flowchart diagram of a method for estimating SOC of a lithium battery according to some embodiments of the present disclosure. As shown in FIG. 1, steps of the method include:

S1: collecting state data and corresponding SOC values of lithium batteries under different working conditions and establishing a sample set, and performing clustering analysis on the sample set to obtain a plurality of sample subsets.

The sample subsets include (X₁,Y₁), (X₂,Y₂), . . . , (Xⱼ,Yⱼ), . . . , (X_{N},Y_{N}), wherein 1≤j≤N, N represents the total number of sample subsets, X represents the state data of the sample subsets, and Y represents the SOC value of the sample subsets. (X₁,Y₁), (X₂,Y₂), . . . , (Xⱼ,Yⱼ), . . . , (X_{N},Y_{N}) are respectively sets of a plurality of samples, i.e., (X₁,Y₁)={(x₁₁,y₁₁), (x₁₂,y₁₂), . . . , (x₁ₐ,y₁ₐ)}, (X₂,Y₂)={(x₂₁,Y₂₁), (x₂₂,y₂₂), . . . , (x_{2b},y_{2b})}, . . . , (Xⱼ,Yⱼ)={(xⱼ₁,yⱼ₁), (xⱼ₂,yⱼ₂), . . . , (x_{jc},y_{jc})}, . . . , (X_{N},Y_{N})={(x_{N1},y_{N1}), (x_{N2},y_{N2}), . . . , (x_{Nn},y_{Nn})}. x represents the state data of a certain sample, y represents the SOC value of a certain sample, and A represents the total number of samples in the sample set.

In some embodiments, the state data includes at least one of charging and discharging current, terminal voltage and temperature of the lithium battery, and the expression formula of state data x of a certain sample is x=[I, U, T], wherein I, U, and T are respectively sampling values of charging and discharging current, terminal voltage and temperature of the lithium battery.

The SOC value refers to the ratio of the remaining capacity of the lithium battery to the capacity of the lithium battery in a fully charged state, and the SOC value ranges from 0% to 100%. When the SOC value is equal to 0%, it means that the lithium battery is fully discharged, and when the SOC value is 100%, it means that the lithium battery is fully charged. By knowing the SOC value, the operation of the lithium battery can be controlled.

Under each working condition, each group of state data x corresponds to an SOC value y, the state data x is an independent variable, and the corresponding SOC value y is a dependent variable. The independent variable x is taken as an input model and the dependent variable y is taken as an output model, and the relationship between the independent variable x and the dependent variable y is calculated to acquire an SOC estimation model of the lithium battery.

The sample sets collected during the above steps are all used as training sets to obtain the SOC estimation model. In the specific application process, in order to test the accuracy of the established SOC estimation model, the sample sets under different working conditions is divided into training sets and test sets. For example, 75% of the sample sets are used as training sets Dₜᵣₐᵢₙ={Xₜᵣₐᵢₙ,Yₜᵣₐᵢₙ} and the other 25% are used as test sets Dₜₑₛₜ={Xₜₑₛₜ,Yₜₑₛₜ}.

In some embodiments, the clustering analysis is used for performing piecewise analysis on the nonlinear lithium battery system for approximate linearization.

In some embodiments, the clustering analysis may adopt any clustering analysis algorithm currently available. In one implementation, the K-means clustering algorithm is used to perform clustering analysis on the sample set, and the specific steps are as follows:

S11: initializing the number N of sample subsets and the maximum iteration number Nᵢₙₜₑᵣ;

S12: randomly selecting the state data of N samples from the sample set as initial cluster centers μ₁, μ₂, . . . , μⱼ, . . . , μ_{N} of N sample subsets (X₁,Y₁), (X₂,Y₂), . . . , (X₁,Yⱼ), . . . , (X_{N},Y_{N}), wherein represents the cluster center, 1≤j≤N;

S13: setting k=1,2, . . . , Nᵢₙₜₑᵣ;

(a) initializing each of the N sample subsets (X₁,Y₁), (X₂,Y₂), . . . , (Xⱼ,Yⱼ), . . . , (X_{N},Y_{N}) into an empty set (Xⱼ,Yⱼ)=φ, j=1,2, . . . , N;

(b) calculating the distance between the state data xᵢ of each sample (xᵢ,yᵢ) and each cluster center j, wherein xᵢ represents the state data of a certain sample and yᵢ represents the SOC value of a certain sample; and the formula for calculation is as follows:

d_{i,j}=∥x₁−μⱼ∥₂²;

(c) putting the sample (xᵢ,yᵢ) into the sample subset (Xⱼ,Yⱼ) corresponding to the smallest d_{i,j}, and updating the sample subset (Xⱼ,Yⱼ)=(Xⱼ,Yⱼ)∩(xᵢ,yᵢ);

(d) calculating the cluster center

$${μ}_{j} = \frac{1}{\vert {X}_{j} \vert} {\sum }_{x ∈ {X}_{j}} x$$

of each updated sample subset, wherein |Xⱼ| is the number of samples of the jth sample subset;

(e) if

$${\sum }_{j = 1}^{N} \vert {μ}_{j} ( k ) - {μ}_{j} ( k - 1 ) \vert \leq 0.01 ,$$

then outputting sample subsets (X₁,Y₁), (X₂,Y₂), (Xⱼ,Yⱼ), . . . , (X_{N},Y_{N}), wherein k=1,2, . . . , Nᵢₙₜₑᵣ;

(f) otherwise, making k←k+1 until the iteration number reaches the maximum iteration number Nᵢₙₜₑᵣ.

S2: establishing a corresponding sub-model for each of the sample subsets to obtain sub-model functions of the plurality of sample subsets.

Linear regression operation is performed on the sample subsets (X₁,Y₁), (X₂,Y₂), . . . , (Xⱼ, Yⱼ), . . . , (X_{N},Y_{N}) after the clustering analysis in the step S1 to acquire a regression classification model for SOC of the lithium battery.

Optionally, partial least squares (PLS) regression method is used to establish a corresponding PLS sub-model for each sample subset so as to obtain PLS sub-model functions of the plurality of sample subsets. PLS is a kind of statistical method which mainly uses the characteristics of principal component analysis to respectively project predicted variables and observed variables into a new space so as to find one linear regression model.

The PLS sub-model is expressed as follows:

$$\{ \begin{matrix}{X}_{j} = {T}_{j} {P}_{j}^{T} + {E}_{{X}_{j}} \\ {Y}_{j} = {U}_{j} {Q}_{j}^{T} + {E}_{{Y}_{j}}\end{matrix} ;$$

wherein Tⱼ and Uⱼ are the score matrices of the jth PLS sub-model, Pⱼ and Qⱼ are the load matrices of the jth PLS sub-model, and E_{Xj} and E_{Yj} are the residual matrices of the jth PLS sub-model;

The score matrices Tⱼ and Uⱼ represent the relationship between each index variable and the extracted common factor. If the score on a certain common factor is high, then it indicates that the relationship between the index variable and the common factor is closer. The load matrices Pⱼ and Qⱼ refer to the coefficients of the factor expressions of various original variables, which mainly represent the degree of influence of the extracted common factor on the original variables. The residual matrices E_{Xj} and E_{Yj} refer to subtracting the estimated value of a sample from the observed value of the sample.

The score matrices are linked by linear regression:

Uⱼ=TⱼBⱼ+Eⱼ

wherein Bⱼ and Eⱼ are respectively the diagonal matrix and regression residual matrix of the jth PLS sub-model. The diagonal matrix refers to a matrix in which all elements other than the main diagonal are 0.

Finally, the PLS sub-model functions of the plurality of sample subsets are expressed as follows:

$$\{ \begin{matrix}{f}_{1} = {T}_{1} {B}_{1} {Q}_{1}^{T} \\ ⋮ \\ {f}_{j} = {T}_{j} {B}_{j} {Q}_{j}^{T} \\ ⋮ \\ {f}_{N} = {T}_{N} {B}_{N} {Q}_{N}^{T}\end{matrix} .$$

Optionally, principal component regression (PCR) is used to establish a corresponding PCR sub-model for each sample subset so as to obtain PCR sub-model functions of the plurality of sample subsets. The PCR sub-model is expressed as follows:

$$\{ \begin{matrix}{g}_{1} = {β}_{1 , 1} {t}_{1 , 1} + {β}_{2 , 1} {t}_{2 , 1} + … + {β}_{h , 1} {t}_{h , 1} \\ ⋮ \\ {g}_{j} = {β}_{1 , j} {t}_{1 , j} + {β}_{2 , j} {t}_{2 , j} + … + {β}_{h , j} {t}_{h , j} \\ ⋮ \\ {g}_{N} = {β}_{1 , N} {t}_{1 , N} + {β}_{2 , N} {t}_{2 , N} + … + {β}_{h , N} {t}_{h , N}\end{matrix}$$

In some embodiments, according to the jth sample subset (Xⱼ,Yⱼ), after the sample matrix Xⱼ is standardized, the covariance matrix Eⱼ thereof may be expressed as follows:

$${\sum }_{j} = \frac{{X}_{j}^{T} {X}_{j}}{n - 1}$$

spectral decomposition is performed thereon:

λⱼP_{i,j}=λ_{i,j}P_{i,j}, i=1,2,3, . . . h;

wherein h is the number of principal components, P_{i,j} is the eigenvector of the covariance matrix, and λX_{i,} j are eigenvalues sorted in the descending order. Representative principal components are extracted to explain most of the changes in the original data:

Xⱼ=t_{1,j}p_{1,j}^{T}+t_{2,j}p_{2,j}^{T}+ . . . +t_{h,j}p_{h,j}^{T}+E_{h,j}

wherein t_{i,j}=XⱼP_{i,j} is the principal component vector. Finally, the PCR sub-model functions of the plurality of sample subsets are expressed as follows:

$$\{ \begin{matrix}{g}_{1} = {β}_{1 , 1} {t}_{1 , 1} + {β}_{2 , 1} {t}_{2 , 1} + … + {β}_{h , 1} {t}_{h , 1} \\ ⋮ \\ {g}_{j} = {β}_{1 , j} {t}_{1 , j} + {β}_{2 , j} {t}_{2 , j} + … + {β}_{h , j} {t}_{h , j} \\ ⋮ \\ {g}_{N} = {β}_{1 , N} {t}_{1 , N} + {β}_{2 , N} {t}_{2 , N} + … + {β}_{h , N} {t}_{h , N}\end{matrix}$$

wherein β_{i,j} is the regression coefficient, and N is the number of sample subsets.

S3: adding the state data of a sample to be tested respectively into the state data of each of the sample subsets, calculating a change value of the state data of each of the sample subsets before and after the adding operation, and selecting at least one sub-model close to the sample to be tested as the selected sub-model according to the change value.

The step of calculating a change value of the state data of each of the sample subsets before and after the adding operation may be performed by KL divergence Kⱼ′, which measures the difference of probability density distribution before and after the change of state data.

In some embodiments, the data state xₜₑₓₜ of the sample to be tested is acquired, and the data state xₜₑₓₜ of the sample to be tested is added to the state data xᵢ, . . . , xⱼ, . . . , x_{N} of each of the sample subsets to obtain new state data (X₁,xₜₑₓₜ), . . . , (Xⱼ,xₜₑₓₜ), . . . , (X_{N},xₜₑₓₜ), and a first divergence information value Kⱼ (KL divergence) between Xⱼ and (Xⱼ,xₜₑₓₜ) is calculated, wherein the formula of the first divergence information value Kⱼ is as follows:

$$\begin{matrix}{K}_{j} = K [ {X}_{j} ‖ ( {X}_{j} , {x}_{test} ) ] \\ = \frac{1}{2} trace \{ ( {\sum }_{1} - {\sum }_{2} ) ( {\sum }_{2}^{- 1} - {\sum }_{1}^{- 1} ) \} + \\ \frac{1}{2} trace \{ ( {\sum }_{2}^{- 1} + {\sum }_{1}^{- 1} ) ( {σ}_{1} - {σ}_{2} ) {( {σ}_{1} - {σ}_{2} )}^{T} \}\end{matrix}$$

wherein Σ₁ and σ₁ are respectively the covariance matrix and mean of Xⱼ, Σ₂ and σ₂ are respectively the covariance matrix and mean of (Xⱼ,xₜₑₓₜ), and trace is the matrix tracing operator.

Normalization processing is performed on the first divergence information value Kⱼ to acquire a second divergence information value Kⱼ′, wherein the formula for normalization is as follows:

$${K}_{j}^{′} = 1 - \frac{{K}_{j} - min ( {K}_{1} , {K}_{2} , … {K}_{N} )}{max ( {K}_{1} , {K}_{2} , … {K}_{N} ) - min ( {K}_{1} , {K}_{2} , … {K}_{N} )} ∈ [ 0 , 1 ] ,$$

a larger Kⱼ′ represents a higher similarity between xₜₑₓₜ and Xⱼ, i.e., xₜₑₓₜ being closer to the working conditions of lithium batteries characterized by Xⱼ. Therefore, N_{c} sub-models corresponding to the larger Kⱼ′ are selected from the sample probability density distribution.

In some embodiments, the second divergence information value Kⱼ′ is compared with a preset divergence information value ε, and the sub-model which corresponds to Kⱼ′ not less than the preset divergence information value ε is taken as the selected sub-model close to the sample to be tested. The expression formula of a set of the selected sub-models is as follows: Q_{c}={q₁,q₂, . . . , q_{N}_{_{c}}}, is determined by the following formula: Q_{c}={j|Kⱼ′≤ε}.

wherein N_{c} is the total number of the selected sub-models.

S4: assigning a weight to the selected sub-model, and calculating the SOC value of the sample to be tested.

The weight of each selected sub-model is related to the second divergence information value Kⱼ′, and the weight of each selected sub-model in the selected sub-models is made to be P(Xₛ|xₜₑₓₜ), s=q₁, q₂, . . . , q_{Nc}.

according to Bayes' total probability formula, the weight thereof may be further expressed as follows:

$$P ( {X}_{s} \vert {x}_{test} ) = \frac{P ( {X}_{s} ) P ( {x}_{test} \vert {X}_{s} )}{{\sum }_{s = {q}_{1}}^{{q}_{{N}_{c}}} P ( {X}_{s} ) P ( {x}_{test} \vert {X}_{s} )}$$

wherein

$$P ( {x}_{test} \vert {X}_{s} ) = \frac{{K}_{s}^{′}}{{\sum }_{s = {q}_{1}}^{{q}_{{N}_{c}}} {K}_{s}^{′}} ,$$

wherein P(Xₛ|xₜₑₛₜ) is the posterior probability that the test sample xₜₑₓₜ belongs to Xₛ, P(Xₛ) is the prior probability that Xₛ can describe the current working condition of the lithium P(xₜₑₛₜ|Xₛ) battery, and represents the probability that xₜₑₓₜ may be generated by Xₛ.

It is assumed that the probability of each sub-model being selected for integration is equal, then:

$$P ( {X}_{s} ) = \frac{1}{{N}_{c}} .$$

The output result of SOC integration estimation corresponding to the test sample xₜₑₓₜ is obtained according to the weight assigned to each selected sub-model and in combination with the sub-model function thereof.

Optionally, when partial least squares (PLS) regression method is used to establish a corresponding PLS sub-model for each sample subset, the output result of SOC integration estimation corresponding to the test sample xₜₑₓₜ is as follows:

$${\hat{y}}_{test} = {\sum }_{s = {q}_{1}}^{{q}_{{N}_{c}}} P ( {X}_{s} \vert {x}_{test} ) {f}_{s} ( {x}_{test} ) = \frac{{\sum }_{s = {q}_{1}}^{{q}_{{N}_{c}}} {K}_{s}^{′} {f}_{s} ( {x}_{test} )}{{\sum }_{s = {q}_{1}}^{{q}_{{N}_{c}}} {K}_{s}^{′}} .$$

When principal component regression (PCR) is used to establish a corresponding PCR sub-model for each sample subset, the output result of SOC integration estimation corresponding to the test sample xₜₑₓₜ is as follows:

$${\hat{y}}_{test} = {\sum }_{s = {q}_{1}}^{{q}_{{N}_{c}}} P ( {X}_{s} \vert {x}_{test} ) {g}_{s} ( {x}_{test} ) = \frac{{\sum }_{s = {q}_{1}}^{{q}_{{N}_{c}}} {K}_{s}^{′} {g}_{s} ( {x}_{test} )}{{\sum }_{s = {q}_{1}}^{{q}_{{N}_{c}}} {K}_{s}^{′}} .$$

In some embodiments, the method for estimating SOC of the lithium battery further includes verifying the SOC estimation model of the lithium battery after acquiring the SOC estimation model. After acquiring the SOC estimation model of the lithium battery, the SOC value obtained by the SOC estimation model of the lithium battery may be verified by root mean square error and average relative error, so as to determine whether the SOC value obtained by the SOC estimation model of the lithium battery is accurate or not.

In some embodiments, the formula of the error term is:

$$RMSE = \sqrt{\frac{1}{l} {\sum }_{p = 1}^{l} {( {y}_{test} - {\hat{y}}_{test} )}^{2}} \\ ARE = \frac{1}{l} {{\sum }_{p = 1}}^{l} \frac{\vert {y}_{test} - {\hat{y}}_{test} \vert}{{y}_{test}} \times 100 \%$$

wherein 1 is the number of test samples,yₜₑₛₜ is the true value of SOC, and ŷₜₑₛₜ is the estimated value of SOC.

The verification results of the SOC estimation model of the lithium battery are shown in the following table.

| Error items | RMSE | ARE/% |
|---|---|---|
| Results | 0.767 | 2.63 |

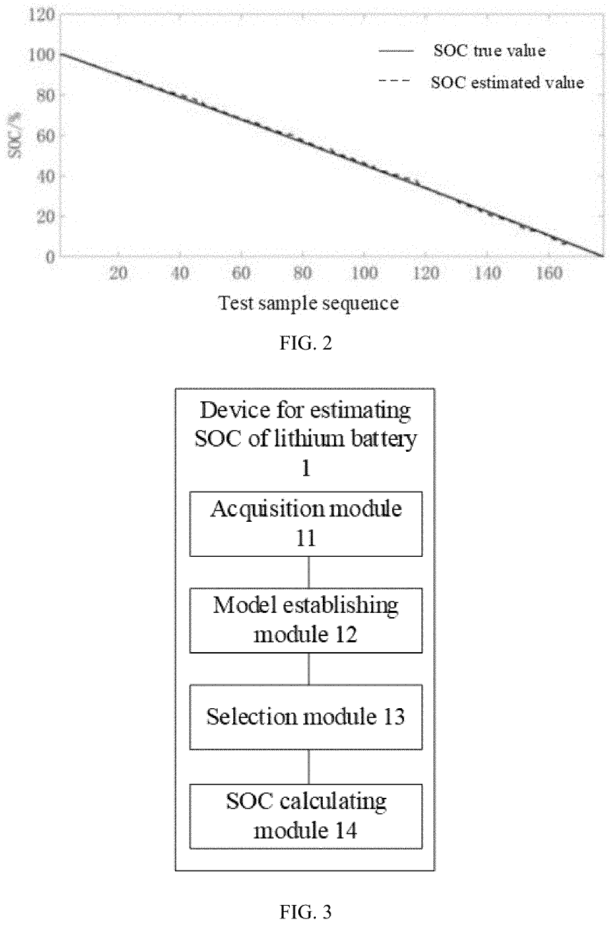

Please refer to FIG. 2, which is a diagram illustrating an estimation result of a method for estimating SOC of a lithium battery according to some embodiments of the present disclosure. The straight line represents the true value of SOC of the lithium battery, and the dotted line represents the estimated value obtained according to the SOC estimation model of the lithium battery. As shown in FIG. 2, the true value of SOC of the lithium battery and the estimated value of SOC of the lithium battery are approximately on the same straight line.

In actual measurement, at least one of the terminal voltage, charging and discharging current and temperature of the lithium battery is acquired in real time, and input into the SOC estimation model of the lithium battery, so as to acquire the corresponding SOC values of the lithium battery corresponding to the terminal voltage, charging and discharging current and temperature.

Different from the situation of related technologies, the embodiments of the present disclosure disclose a method for estimating SOC of a lithium battery, in the method for estimating SOC of the lithium battery, state data and corresponding SOC values of lithium batteries under different working conditions are collected to establish a sample set, and clustering analysis is performed on the sample set to obtain a plurality of sample subsets; then a corresponding sub-model is established for each of the sample subsets to obtain sub-model functions of the plurality of sample subsets; next, the state data of a sample to be tested is respectively added into the state data of each of the sample subsets to calculate a change value of the state data of each of the sample subsets before and after the adding operation, and at least one sub-model close to the sample to be tested is selected as the selected sub-model according to the change value; and finally, a weight is assigned to the selected sub-model to calculate the SOC value of the sample to be tested. By obtaining the estimated SOC value of the lithium battery in the aforementioned manner, the accuracy and reliability of the estimated SOC value of the lithium battery are improved.

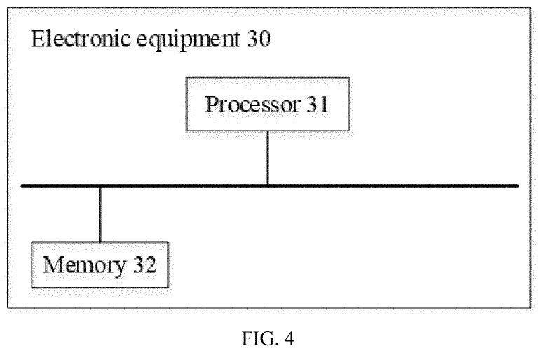

Please refer to FIG. 3, which is a structural block diagram of a device for estimating SOC of a lithium battery according to some embodiments of the present disclosure. As shown in FIG. 3, the device 1 for estimating SOC of the lithium battery includes an acquisition module 11, a model establishing module 12, a selection module 13 and an SOC calculating module 14.

The acquisition module 11 is configured to collect state data and corresponding SOC values of lithium batteries under different working conditions and establish a sample set, and perform clustering analysis on the sample set to obtain a plurality of sample subsets.

The model establishing module 12 is configured to establish a corresponding sub-model for each of the sample subsets to obtain sub-model functions of the plurality of sample subsets.

The selection module 13 is configured to add the state data of a sample to be tested respectively into the state data of each of the sample subsets, calculate a change value of the state data of each of the sample subsets before and after the adding operation, and select at least one sub-model close to the sample to be tested as the selected sub-model according to the change value.

The SOC calculating module 14 is configured to assign a weight to the selected sub-model, and calculate the SOC value of the sample to be tested.

It shall be noted that the device for estimating SOC of the lithium battery described above can execute the method for estimating SOC of the lithium battery disclosed according to the embodiment of the present disclosure, and has corresponding functional modules and beneficial effects for executing the method. For the technical details not described in detail in the embodiment of the device for estimating SOC of the lithium battery, please refer to the method for estimating SOC of the lithium battery disclosed according to the embodiment of the present disclosure.

The embodiments of the device described above are for illustrative purpose. The units illustrated as separate components may be or may not be physically separated, and components displayed as units may be or may not be physical units. That is, these units and components may be located in one place or distributed over multiple network units. Some or all of the modules may be selected according to actual needs to achieve the purpose of the solution of the embodiments.

Referring to FIG. 4, some embodiments of the present disclosure discloses an electronic equipment 30, which includes: at least one processor 31, one processor 31 being taken as an example in FIG. 4; and a memory 32 communicatively connected to the at least one processor 31, connection through a bus being taken as an example in FIG. 4.

The memory 32 stores instructions that can be executed by the at least one processor 31, and the instructions are executed by the at least one processor 31 to enable the at least one processor 31 to execute the method for estimating SOC of the lithium battery described above.

As a nonvolatile computer readable storage medium, the memory 32 is used to store nonvolatile software programs, nonvolatile computer executable programs and modules, such as program instructions/modules corresponding to the method for estimating SOC of the lithium battery in the embodiments of the present disclosure. The processor 31 runs the nonvolatile software programs, instructions and modules stored in the memory 32, thereby executing various functional applications and data processing of the electronic equipment 30, i.e., implementing the method for estimating SOC of the lithium battery disclosed by the embodiments of the method described above.

The memory 32 includes a program storage area and a data storage area, wherein the program storage area stores operating systems and application programs required by at least one function. In addition, the memory 32 may include a high-speed random access memory, and also includes a nonvolatile memory. For example, the memory 32 includes at least one magnetic disk memory device, flash memory device, or other nonvolatile solid-state memory device. In some embodiments, the memory 32 optionally includes memories remotely disclosed relative to the processor 31.

The one or more modules are stored in the memory 32, and when executed by the one or more processors 31, the one or more modules execute the method for estimating SOC of the lithium battery in any of the embodiments of the method described above, e.g., execute the steps of the method of FIG. 1 described above.

The electronic equipment described above may execute the method disclosed according to the embodiments of the present disclosure, and have corresponding functional modules for executing the method. For technical details not described in detail in this embodiment, please refer to the method disclosed according to the embodiments of the present disclosure.

The electronic equipment of the embodiment of the present disclosure exists in various forms, including but not limited to:

(1) an ultra-mobile personal computer equipment: this kind of equipment belongs to the category of personal computers, which have the functions of calculating and processing, and generally also have the characteristics of mobile Internet access. Such terminals include PDA, MID and UMPC equipments, such as iPad.

(2) a server: it is an equipment that discloses computing services, and the components of the server include processor, hard disk, memory, system bus or the like. The architecture of the server is similar to that of a general computer, but due to the need of providing highly reliable services, it requires higher processing power, stability, reliability, security, scalability, manageability or the like.

(3) Other electronic devices with data interaction function.

An embodiment of the present disclosure further discloses a computer readable storage medium, in which computer executable instructions are stored. The computer executable instructions are executed by one or more processors to for example execute the steps of the method of FIG. 1 described above and implement the functions of the modules in FIG. 3.

An embodiment of the present disclosure discloses a computer program product, which includes a computer program stored on a nonvolatile computer readable storage medium. The computer program includes program instructions which, when executed by the electronic equipment, enable the electronic equipment to execute the method for estimating SOC of the lithium battery in any of the embodiments of the method described above, e.g., execute the steps S1 to S4 of the method of FIG. 1 described above and implement the function of modules 11 to 14 in FIG. 3.

The embodiments of the device described above are for illustrative purpose. The units illustrated as separate components may be or may not be physically separated, and components displayed as units may be or may not be physical units. That is, these units and components may be located in one place or distributed over multiple network units. Some or all of the modules may be selected according to actual needs to achieve the purpose of the solution of the embodiments.

From the description of the above embodiments, those of ordinary skill in the art may clearly appreciate that each embodiment may be realized by means of software plus a general hardware platform, and of course, it may also be realized by hardware. As shall be appreciated by those of ordinary skill in the art, the implementation of all or part of the processes in the embodiments of the method described above may be completed by instructing related hardware through a computer program, and the program may be stored in a computer readable storage medium. When it is executed, the program may include the processes of the embodiments of the methods described above. The storage medium may be a magnetic disk, an optical disk, a Read-Only Memory (ROM) or a Random Access Memory (RAM) or the like.

Finally, it shall be noted that, the above embodiments are used to illustrate the technical solutions of the present disclosure, and are not intended to limit the present disclosure. Under the idea of the present disclosure, technical features in the above embodiments or different embodiments may also be combined, the steps may be implemented in any order, and many other variations in different aspects of the present disclosure as described above are possible, and these variations are not disclosed in details for conciseness. Although the present disclosure has been described in detail with reference to the foregoing embodiments, those of ordinary skill in the art shall appreciate that, the technical solutions described in the foregoing embodiments may still be modified or some of the technical features may be equivalently replaced. These modifications or replacements do not make the essence of the corresponding technical solutions deviate from the scope of the technical solutions of various embodiment of the present disclosure.

What is claimed is:

1. A method for estimating SOC of a lithium battery, comprising:
collecting state data and corresponding SOC values of lithium batteries under different working conditions and establishing a sample set, and performing clustering analysis on the sample set to obtain a plurality of sample subsets;
establishing a corresponding sub-model for each of the sample subsets by performing linear regression operation to obtain sub-model functions of the plurality of sample subsets;
adding the state data of a sample to be tested respectively into the state data of each of the sample subsets, calculating a change value of the state data of each of the sample subsets before and after the adding operation, and selecting at least one sub-model close to the sample to be tested as the selected sub-model according to the change value;
assigning a weight to the selected sub-model, and calculating the SOC value of the sample to be tested;
the step of assigning a weight to the selected sub-model comprises:
making the weight of each selected sub-model in the selected sub-models be P(Xₛ|xₜₑₓₜ), s=q₁, q₂, . . . , q_{Nc};
the expression formula of the weight is as follows:
$$P ( {X}_{s} \vert {x}_{test} ) = \frac{P ( {X}_{s} ) P ( {x}_{test} \vert {X}_{s} )}{{\sum }_{s = {q}_{1}}^{{q}_{{N}_{c}}} P ( {X}_{s} ) P ( {x}_{test} \vert {X}_{s} )}$$
wherein
$$P ( {x}_{test} \vert {X}_{s} ) = \frac{{K}_{s}^{′}}{{\sum }_{s = {q}_{1}}^{{q}_{{N}_{c}}} {K}_{s}^{′}} \\ P ( {X}_{s} ) = \frac{1}{{N}_{c}} ;$$
wherein P(Xₛ) is the prior probability that Xₛ can describe the current working condition of the lithium battery, P(Xₛ|xₜₑₓₜ) represents the probability that xₜₑₓₜ may be generated by Xₛ;
the step of calculating the SOC value of the sample to be tested is to calculate the SOC value through the following formula:
$${\hat{y}}_{test} = {\sum }_{s = {q}_{1}}^{{q}_{{N}_{c}}} P ( {X}_{s} \vert {x}_{test} ) {f}_{s} ( {x}_{test} ) = \frac{{\sum }_{s = {q}_{1}}^{{q}_{{N}_{c}}} {K}_{s}^{′} {f}_{s} ( {x}_{test} )}{{\sum }_{s = {q}_{1}}^{{q}_{{N}_{c}}} {K}_{s}^{′}} ;$$
wherein ŷₜₑₛₜ is the estimated value of SOC, xₜₑₓₜ is the state data of a sample to be tested, q₁ is the selected 1^{st} sub-model, q_{Nc} is the selected Nc^{st} sub-model, s is the selected s^{st} sub-model, P(Xₛ|xₜₑₓₜ) is the weight of the selected s^{st} sub-model, fₛ(xₜₑₓₜ) is the sub-model function of the selected s^{st} sub-model, K_{S}′ is the divergence information value.

2. The method according to claim 1, wherein the state data of the lithium battery comprises at least one of charging and discharging current, terminal voltage and temperature of the lithium battery.

3. The method according to claim 1, wherein the step of performing clustering analysis on the sample set to obtain a plurality of sample subsets comprises: performing clustering analysis on the sample set to obtain a plurality of sample subsets by using the K-means algorithm, which comprises steps of:
initializing the number N of sample subsets and the maximum iteration number Nᵢₙₜₑᵣ;
randomly selecting the state data of N samples from the sample set as centers μ₁, μ₂, . . . , μⱼ, . . . , μ_{N} of N sample subsets (X₁,Y₁), (X₂,Y₂), . . . , (Xⱼ,Yⱼ), . . . , (X_{N},Y_{N}), wherein X represents the state data, Y represents the SOC value, and represents the cluster center, 1≤j≤N;
setting k=1,2, . . . , Nᵢₙₜₑᵣ;
initializing each of the N sample subsets (X₁,Y₁), (X₂,Y₂), . . . , (Xⱼ,Yⱼ), . . . , (X_{N},Y_{N}) into an empty set (Xⱼ,Yⱼ)=φ, j=1,2, . . . , N;
calculating the distance between the state data xᵢ of each sample (xᵢ,yᵢ) and each cluster center j, wherein xᵢ represents the state data of a certain sample and yᵢ represents the SOC value of a certain sample; and the formula for calculation is as follows:
d_{i,j}=∥xᵢ−μⱼ∥₂²
putting the sample (xᵢ,yᵢ) into the sample subset (Xⱼ,Yⱼ) corresponding to the smallest d_{i,j}, and updating the sample subset (Xⱼ,Yⱼ)=(Xⱼ,Yⱼ)∩(xᵢ,yᵢ);
calculating the cluster center
$${μ}_{j} = \frac{1}{\vert {X}_{j} \vert} {\sum }_{x ∈ {X}_{j}} x$$
of each updated sample subset,
wherein |Xⱼ| is the number of samples of the jth sample subset;
if
$${\sum }_{j = 1}^{N} \vert {μ}_{j} ( k ) - {μ}_{j} ( k - 1 ) \vert \leq 0.01 ,$$
then outputting sample subsets (X₁,Y₁), (X₂,Y₂), . . . , (Xⱼ,Yⱼ), . . . , (X_{N},Y_{N}), wherein k=1,2, . . . , Nᵢₙₜₑᵣ;
otherwise, making k←k+1 until the iteration number reaches the maximum iteration number Nᵢₙₜₑᵣ.

4. The method according to claim 1, wherein the step of establishing a corresponding sub-model for each of the sample subsets to obtain sub-model functions of the plurality of sample subsets comprises: establishing a corresponding PLS sub-model for each of the sample subsets by using a partial least squares regression method to obtain PLS sub-model functions of the plurality of sample subsets;
the PLS sub-model is expressed as follows:
$$\{ \begin{matrix}{X}_{j} = {T}_{j} {P}_{j}^{T} + {E}_{{X}_{j}} \\ {Y}_{j} = {U}_{j} {Q}_{j}^{T} + {E}_{{Y}_{j}}\end{matrix}$$
wherein Tⱼ and Uⱼ are the score matrices of the jth PLS sub-model, Pⱼ and Qⱼ are the load matrices of the jth PLS sub-model, and E_{Xj} and E_{Yj} are the residual matrices of the jth PLS sub-model;
the score matrices are linked by linear regression:
Uⱼ=TⱼBⱼ+Eⱼ
wherein Bⱼ and Eⱼ are the diagonal matrix and regression residual matrix of the jth PLS sub-model respectively;
the PLS sub-model functions of the plurality of sample subsets are expressed as follows:
$$\{ \begin{matrix}{f}_{1} = {T}_{1} {B}_{1} {Q}_{1}^{T} \\ ⋮ \\ {f}_{j} = {T}_{j} {B}_{j} {Q}_{j}^{T} \\ ⋮ \\ {f}_{N} = {T}_{N} {B}_{N} {Q}_{N}^{T}\end{matrix}$$
wherein f represents the sub-model function.

5. The method according to claim 1, wherein the operation of adding the state data of a sample to be tested respectively into the state data of each of the sample subsets and calculating a change value of the state data of each of the sample subsets before and after the adding operation comprises:
adding the state data xₜₑₓₜ of the sample to be tested respectively into the state data xᵢ, . . . , xⱼ, . . . , x_{N} of each of the sample subsets to obtain new state data (X₁,xₜₑₓₜ), . . . , (Xⱼ,xₜₑₓₜ), . . . , (X_{N},xₜₑₓₜ);
calculating a first divergence information value Kⱼ between Xⱼ and (Xⱼ,xₜₑₓₜ), wherein the formula of the first divergence information value Kⱼ is as follows:
$$\begin{matrix}{K}_{j} = K [ {X}_{j} ‖ ( {X}_{j} , {x}_{test} ) ] \\ = \frac{1}{2} trace \{ ( {\sum }_{1} - {\sum }_{2} ) ( {\sum }_{2}^{- 1} - {\sum }_{1}^{- 1} ) \} + \frac{1}{2} trace \{ ( {\sum }_{1}^{- 1} + {\sum }_{2}^{- 1} ) ( {σ}_{1} - {σ}_{2} ) {( {σ}_{1} - {σ}_{2} )}^{T} \}\end{matrix}$$
wherein Σ₁ and σ₁ are respectively the covariance matrix and mean of Xⱼ, Σ₂ and σ₂ are respectively the covariance matrix and mean of (Xⱼ,xₜₑₓₜ), and trace is the matrix tracing operator;
performing normalization processing on the first divergence information value Kⱼ to obtain a second divergence information value Kⱼ′, wherein the formula for normalization is as follows:
$${K}_{j}^{′} = 1 - \frac{{K}_{j} - min ( {K}_{1} , {K}_{2} , … {K}_{N} )}{max ( {K}_{1} , {K}_{2} , … {K}_{N} ) - min ( {K}_{1} , {K}_{2} , … {K}_{N} )} ∈ [ 0 , 1 ] .$$

6. The method according to claim 5, wherein the step of selecting at least one sub-model close to the sample to be tested as the selected sub-model according to the change value comprises:
comparing Kⱼ′ with a preset divergence information value ε, and taking the sub-model which corresponds to Kⱼ′ not less than the preset divergence information value ε as the selected sub-model close to the sample to be tested, and the expression formula of a set of the selected sub-models is as follows:
Q_{c}={q₁,q₂, . . . , q_{N}_{_{c}}},Q_{c}={j|Kⱼ′≤ε},
wherein N, is the total number of the selected sub-models, q₁, q₂, . . . , q_{Nc} is the 1^{st},second, . . . Nc^{st} sub-model.

7. A computer readable storage medium, having computer executable instructions stored therein, the computer executable instructions enabling a computer to execute a method for estimating SOC of a lithium battery, wherein the method for estimating SOC of a lithium battery comprises:
collecting state data and corresponding SOC values of lithium batteries under different working conditions and establishing a sample set, and performing clustering analysis on the sample set to obtain a plurality of sample subsets;
establishing a corresponding sub-model for each of the sample subsets by performing linear regression operation to obtain sub-model functions of the plurality of sample subsets;
adding the state data of a sample to be tested respectively into the state data of each of the sample subsets, calculating a change value of the state data of each of the sample subsets before and after the adding operation, and selecting at least one sub-model close to the sample to be tested as the selected sub-model according to the change value;
assigning a weight to the selected sub-model, and calculating the SOC value of the sample to be tested;
the step of assigning a weight to the selected sub-model comprises:
making the weight of each selected sub-model in the selected sub-models be P(Xₛ|xₜₑₓₜ), s=q₁, q₂, . . . , q_{Nc};
the expression formula of the weight is as follows:
$$P ( {X}_{s} \vert {x}_{test} ) = \frac{P ( {X}_{s} ) P ( {x}_{test} \vert {X}_{s} )}{{\sum }_{s = {q}_{1}}^{{q}_{{N}_{c}}} P ( {X}_{s} ) P ( {x}_{test} \vert {X}_{s} )}$$
$$wherein$$
$$P ( {x}_{test} \vert {X}_{s} ) = \frac{{K}_{s}^{′}}{{\sum }_{s = {q}_{1}}^{{q}_{{N}_{c}}} {K}_{s}^{′}}$$
$$P ( {X}_{s} ) = \frac{1}{{N}_{c}} ;$$
wherein P(Xₛ) is the prior probability that Xₛ can describe the current working condition of the lithium battery, P(Xₛ|xₜₑₓₜ) represents the probability that xₜₑₓₜ may be generated by Xₛ;
the step of calculating the SOC value of the sample to be tested is to calculate the SOC value through the following formula:
$${\hat{y}}_{test} = {\sum }_{s = {q}_{1}}^{{q}_{{N}_{c}}} P ( {X}_{s} \vert {x}_{test} ) {f}_{s} ( {x}_{test} ) = \frac{{\sum }_{s = {q}_{1}}^{{q}_{{N}_{c}}} {K}_{s}^{′} {f}_{s} ( {x}_{test} )}{{\sum }_{s = {q}_{1}}^{{q}_{{N}_{c}}} {K}_{s}^{′}} ;$$
wherein ŷₜₑₛₜ is the estimated value of SOC, xₜₑₓₜ is the state data of a sample to be tested, q₁ is the selected 1^{st} sub-model, q_{Nc} is the selected Nc^{st} sub-model, s is the selected s^{st} sub-model, P(Xₛ|xₜₑₓₜ) is the weight of the selected s^{st} sub-model, fₛ(xₜₑₓₜ) is the sub-model function of the selected s^{st} sub-model, K_{S}′ is the divergence information value.

8. The computer readable storage medium according to claim 7, wherein the state data of the lithium battery comprises at least one of charging and discharging current, terminal voltage and temperature of the lithium battery.

9. The computer readable storage medium according to claim 7, wherein the step of performing clustering analysis on the sample set to obtain a plurality of sample subsets comprises: performing clustering analysis on the sample set to obtain a plurality of sample subsets by using the K-means algorithm, which comprises steps of:
initializing the number N of sample subsets and the maximum iteration number Nᵢₙₜₑᵣ;
randomly selecting the state data of N samples from the sample set as centers μ₁, μ₂, . . . , μⱼ, . . . , μ_{N} of N sample subsets (X₁,Y₁), (X₂,Y₂), . . . , (Xⱼ,Yⱼ), . . . , (X_{N}Y_{N}), wherein X represents the state data, Y represents the SOC value, and represents the cluster center, 1≤j≤N;
setting k=1,2, . . . , Nᵢₙₜₑᵣ;
initializing each of the N sample subsets (X₁,Y₁), (X₂,Y₂), . . . , (Xⱼ,Yⱼ), . . . , (X_{N},Y_{N}) into an empty set (Xⱼ,Yⱼ)=φ, j=1,2, . . . , N;
calculating the distance between the state data xᵢ of each sample (xᵢ,yᵢ) and each cluster center μⱼ, wherein xᵢ represents the state data of a certain sample and yᵢ represents the SOC value of a certain sample; and the formula for calculation is as follows:
d_{i,j}=∥x₁−μⱼ∥₂²;
putting the sample (xᵢ,yᵢ) into the sample subset (Xⱼ,Yⱼ) corresponding to the smallest d_{i,j}, and updating the sample subset (Xⱼ,Yⱼ)=(Xⱼ,Yⱼ)∩(xᵢ,yᵢ);
calculating the cluster center
$${μ}_{j} = \frac{1}{\vert {X}_{j} \vert} {\sum }_{x ∈ {X}_{j}} x$$
of each updated sample subset, wherein |Xⱼ| is the number of samples of the jth sample subset;
if
$${\sum }_{j = 1}^{N} \vert {μ}_{j} ( k ) - {μ}_{j} ( k - 1 ) \vert \leq 0.01 ,$$
then outputting sample subsets (X₁,Y₁), (X₂,Y₂), . . . , (Xⱼ,Yⱼ), . . . , (X_{N},Y_{N}), wherein k=1,2, . . . , Nᵢₙₜₑᵣ;
otherwise, making k←k+1 until the iteration number reaches the maximum iteration number Nᵢₙₜₑᵣ.

10. The computer readable storage medium according to claim 7, wherein the step of establishing a corresponding sub-model for each of the sample subsets to obtain sub-model functions of the plurality of sample subsets comprises: establishing a corresponding PLS sub-model for each of the sample subsets by using a partial least squares regression method to obtain PLS sub-model functions of the plurality of sample subsets;
the PLS sub-model is expressed as follows:
$$\{ \begin{matrix}{X}_{j} = {T}_{j} {P}_{j}^{T} + {E}_{{X}_{j}} \\ {Y}_{j} = {U}_{j} {Q}_{j}^{T} + {E}_{{Y}_{j}}\end{matrix}$$
wherein Tⱼ and Uⱼ are the score matrices of the jth PLS sub-model, Pⱼ and Qⱼ are the load matrices of the jth PLS sub-model, and E_{Xj} and E_{Yj} are the residual matrices of the jth PLS sub-model;
the score matrices are linked by linear regression:
Uⱼ=TⱼBⱼ+Eⱼ
wherein Bⱼ and Eⱼ are the diagonal matrix and regression residual matrix of the jth PLS sub-model respectively;
the PLS sub-model functions of the plurality of sample subsets are expressed as follows:
$$\{ \begin{matrix}{f}_{1} = {T}_{1} {B}_{1} {Q}_{1}^{T} \\ ⋮ \\ {f}_{j} = {T}_{j} {B}_{j} {Q}_{j}^{T} \\ ⋮ \\ {f}_{N} = {T}_{N} {B}_{N} {Q}_{N}^{T}\end{matrix}$$
wherein f represents the sub-model function.

11. The computer readable storage medium according to claim 7, wherein the operation of adding the state data of a sample to be tested respectively into the state data of each of the sample subsets and calculating a change value of the state data of each of the sample subsets before and after the adding operation comprises:
adding the state data xₜₑₓₜ of the sample to be tested respectively into the state data x₁, . . . , xⱼ, . . . , x of each of the sample subsets to obtain new state data (X₁,xₜₑₓₜ), . . . , (Xⱼ,xₜₑₓₜ), . . . , (X_{N},xₜₑₓₜ);
calculating a first divergence information value Kⱼ between Xⱼ and (Xⱼ,xₜₑₓₜ), wherein the formula of the first divergence information value Kⱼ is as follows:
$$\begin{matrix}{K}_{j} = K [ {X}_{j} ‖ ( {X}_{j} , {x}_{test} ) ] \\ = \frac{1}{2} trace \{ ( {\sum }_{1} - {\sum }_{2} ) ( {\sum }_{2}^{- 1} - {\sum }_{1}^{- 1} ) \} + \frac{1}{2} trace \{ ( {\sum }_{1}^{- 1} + {\sum }_{2}^{- 1} ) ( {σ}_{1} - {σ}_{2} ) {( {σ}_{1} - {σ}_{2} )}^{T} \}\end{matrix}$$
wherein Σ₁ and σ₁ are respectively the covariance matrix and mean of Xⱼ, Σ₂ and σ₂ are respectively the covariance matrix and mean of (Xⱼ,xₜₑₓₜ), and trace is the matrix tracing operator;
performing normalization processing on the first divergence information value Kⱼ to obtain a second divergence information value Kⱼ′, wherein the formula for normalization is as follows:
$${K}_{j}^{′} = 1 - \frac{{K}_{j} - min ( {K}_{1} , {K}_{2} , … {K}_{N} )}{max ( {K}_{1} , {K}_{2} , … {K}_{N} ) - min ( {K}_{1} , {K}_{2} , … {K}_{N} )} ∈ [ 0 , 1 ] .$$

12. The computer readable storage medium according to claim 11, wherein the step of selecting at least one sub-model close to the sample to be tested as the selected sub-model according to the change value comprises:
comparing Kⱼ′ with a preset divergence information value ε, and taking the sub-model which corresponds to Kⱼ′ not less than the preset divergence information value ε as the selected sub-model close to the sample to be tested, and the expression formula of a set of the selected sub-models is as follows:
Q_{c}={q₁,q₂, . . . , q_{N}_{_{c}}},Q_{c}={j|Kⱼ′≤ε},
wherein N_{c} is the total number of the selected sub-models, q₁, q₂, . . . , q_{Nc} is the 1^{st}, second, . . . , Nc^{st} sub-model.
